(19) United States
(12) Patent Application Publication
(10) Pub. No.: US 2025/0115520 A1
(43) Pub. Date: Apr. 10, 2025

(54) POWDER, LAMINATE USING THE SAME, AND METHOD OF MANUFACTURING LAMINATE

(71) Applicants: Hidetoshi Kami, Chiba (JP); Ryota Inoue, Shizuoka (JP)

(72) Inventors: Hidetoshi Kami, Chiba (JP); Ryota Inoue, Shizuoka (JP)

(73) Assignee: Ricoh Company, Ltd., Tokyo (JP)

(21) Appl. No.: 18/688,679

(22) PCT Filed: Sep. 13, 2022
(86) PCT No.: PCT/IB2022/058597

§ 371 Date: Mar. 1, 2024

(30) Foreign Application Priority Data
Sep. 16, 2021 (JP) 2021-150973

(51) Int. Cl. C04B 35/10; C04B 35/45; C04B 35/622

(52) U.S. Cl. CPC C04B 35/10; C04B 35/45; C04B 35/62222; C04B 2235/3217; C04B 2235/3281; C04B 2235/5436; C04B 2235/5445; C04B 2235/77

(57) ABSTRACT

A powder contains a metal oxide and satisfies the following conditions: the powder has peaks of a particle size in a range of from 0.1 to less than 5 μm and in a range of from 5 to less than 50 μm in a frequency distribution curve based on a volume-based particle size distribution obtained by a laser diffraction method. The second condition is that a difference between a tap density and an initial bulk density satisfies the following relationship 0.88 g/cm³≤(tap density−initial bulk density)≤0.94 g/cm³.

### TECHNICAL FIELD

The present disclosure is related to a powder, a laminate using the powder, and a method of manufacturing a laminate.

### BACKGROUND ART

There is a method referred to as aerosol deposition (AD) method for forming a ceramic layer on the surface of a substrate at room temperature. In the AD method, metal materials such as stainless steel and iron or glass is generally used as a substrate for ceramic coating. Currently, a ceramic coating technology to a resin material is developed.

This ceramic coating requires a ceramic material to be sufficiently attached to a substrate. In addition, ceramic coating film is required to be tough enough to suit to the performance of bulk ceramic. The attachability and toughness of a coated surface are issues in view of the industrial use of ceramic coating on resin materials.

Forming an aggregate layer has been proposed in Japanese Translation of PCT International Application Publication No. JP-T-2017/199968 (PTL 1) in which the aggregate layer of secondary particles of inorganic materials is formed on an intermediate layer of an inorganic-organic hybrid member of primary inorganic particles covalently bonded with organic polymers, the intermediate layer being formed on an organic material substrate. This aggregate layer of secondary particles can be interpreted as a ceramic layer. This intermediate layer is designed to: (1) reduce the repulsion of inorganic particles sprayed to a resin substrate due to the resilience of a resin substrate; (2) enhance the blast resistance of the substrate in the ceramic coating by the AD method; and (3) improve the anchor effect of the substrate. The organic-inorganic hybrid material used is a copolymer of alkoxysilane and polyamic acid, an isocyanate compound, an epoxy compound, or a phenol.

Forming a stress relaxing layer has been proposed in Japanese Translation of PCT International Application Publication No. JP-T-2018/194064 (PTL 2) in which the stress relaxing layer that can be referred to as a primer is formed between the substrate and the intermediate layer mentioned above. If film shrinks during forming an inorganic layer, the inorganic layer peels off from the substrate. The stress relaxing layer is designed to prevent peeling-off and cracking of a ceramic layer by designing the viscoelasticity of a material that prevents this peeling-off.

The ceramic coating on a resin material requires such an improvement on ceramic material that forms film in addition to the improvement on a substrate.

Using a mixture of ceramic materials having different hardness has been proposed in Japanese Unexamined Patent Application Publication No. 2020-180346 (PTL 3). The mixture reduces the residual compressive stress occurring during film formation of a ceramic layer and fills gaps between hard particles with readily deformable particles. A ceramic laminate manufactured by using this material is not readily peeled.

An aggregate of powdered fine particles and ground powder produced by pulverizing zirconia powder has been proposed in Japanese Unexamined Patent Application Publication No. 2017-179421 (PTL 4). By adjusting the ratio of the particle size distributions of the two types of powdered particles, a thick and white zirconia film having a thickness of several tens or more μm can be formed on a substrate.

Applying a thermal shock to ceramic powder has been proposed in Japanese Unexamined Patent Application Publication No. 2008-056948 (PTL 5). By this application, cracks and stress strain are imparted to the surface and inside of fine particles of the ceramic powder. The thermal shock is a treatment of rapid cooling of ceramic powder after holding the powder at 500 to 1,100 degrees C. for 10 minutes or more. After this shock, the ceramic powder is readily pulverized at the collision with a substrate in the ceramic coating by the AD method, which enhances the efficiency of forming a ceramic film on the substrate.

### CITATION LIST

### Patent Literature

[PTL 1] Japanese Translation of PCT International Application Publication No. JP-T-2017/199968
[PTL 2] Japanese Translation of PCT International Application Publication No. JP-T-2018/194064
[PTL 3] Japanese Unexamined Patent Application Publication No. 2020-180346
[PTL 4] Japanese Unexamined Patent Application Publication No. 2017-179421
[PTL 5] Japanese Unexamined Patent Application Publication No. 2008-056948

### SUMMARY OF INVENTION

### Technical Problem

Since the toughness of the surface of a metal oxide produced by the AD method depends on a powder material used for film-forming, a substrate, and the film forming conditions, it is not possible to uniquely determine the way of toughening. The film forming condition for enhancing the toughness should be determined for each specific material. This condition determination becomes more difficult for a substrate of an organic substance so that a satisfactory condition may not be found. For this reason, there has been demand for a more latitude of freedom of enabling the AD method about powdered material, substrate, and film-forming conditions.

### Solution to Problem

The issues mentioned above can be solved by the following configuration (1). Powder contains a metal oxide, satisfying the following conditions (1) and (2).
(1) The powder has peaks of a particle size in a range of from 0.1 to less than 5 μm and a range of from 5 to less than 50 μm in a frequency distribution curve based on volume-based particle size distribution obtained by a laser diffraction method and
(2) the difference between the tap density and the initial bulk density satisfies the following Relationship:

0.88 g/cm³≤(tap density−initial bulk density)≤0.94 g/cm³.

### Advantageous Effects of Invention

According to the present disclosure, a powder is provided which can readily produce a tough surface of a metal oxide regarding coating on the metal oxide.

### BRIEF DESCRIPTION OF DRAWINGS

A more complete appreciation of embodiments of the present disclosure and many of the attendant advantages and features thereof can be readily obtained and understood from the following detailed description with reference to the accompanying drawings

FIG. 1 is a schematic diagram illustrating the mechanism of ceramic coating by the AD method.

FIG. 2 is a graph of an example of a particle size distribution of a metal oxide powder.

FIG. 3 is a graph of an example of another particle size distribution of a metal oxide powder.

FIG. 4 is diagram illustrating a view of a perovskite solar cell, a laminate according to an embodiment of the present disclosure.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DESCRIPTION OF EMBODIMENTS

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

Embodiments of the present disclosure are described in detail below.

As described above, the powder of the powder layer contains a metal oxide and satisfies the following (1) and (2).
(1) The powder has peaks of a particle size in a range of from 0.1 to less than 5 μm and a range of from 5 to less than 50 μm in a frequency distribution curve based on volume-based particle size distribution obtained by a laser diffraction method and
(2) the difference between the tap density and the initial bulk density satisfies the following Relationship:

0.88 g/cm³≤(tap density−initial bulk density)≤0.94 g/cm³.

The powder of the present disclosure readily produces a tough surface of an organic metal material, which is soft and brittle and clearly distinct from an organic material such as glass, metal, and ceramics.

The powder of the present disclosure can be applied to ceramic coatings by the AD process. This powder is used as a material for firmly coating an organic material substrate with a metal oxide particularly in the AD method.

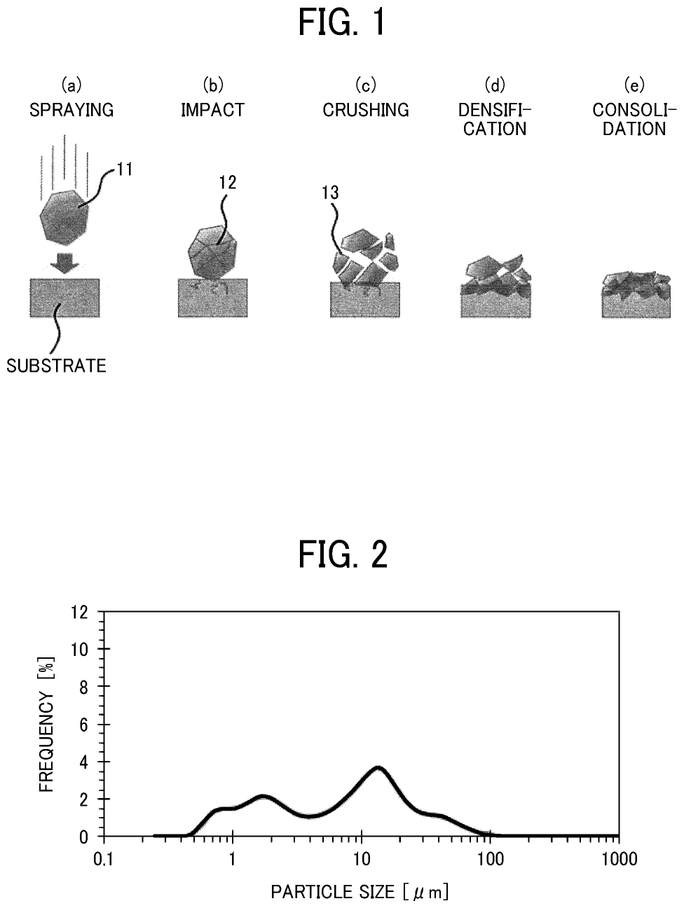

The following explains the mechanism of ceramic coating by the AD method with reference to FIG. 1. A ceramic particle 11 sprayed onto a substrate by the AD method causes cracks 12 at the impact (FIGS. 1(a) to 1(b)). Then the particle crushes into fine pieces and an active new surface 13 appears at the fracture surface of the crushed particle (FIG. 1(c)). The fine crystalline fragment having such an active new surface 13 moves or rotates on the substrate due to the inertial moment and the impact pressure, which promotes densification (FIG. 1(d)). The active new surfaces recombine and consolidate (FIG. 1(e)).

FIG. 1 is a conceptual diagram illustrating a simplified film-forming process of the ceramic particle 1 by the AD method.

The ceramic film is formed through the sequential changes in the order of FIGS. 1(a) to 1(e). However, actually the states (a) to (e) in FIG. 1 are considered to be present at the same time. Inferentially, the ceramic coating exhibits various phases in accordance with the probability of these states.

In the spraying phase at FIG. 1(a), the erosion of the substrate surface is focused. If the manner how the ceramic particle 1 collides with the substrate is similar to that of sandblasting, the surface of the substrate erodes. The particle size of the ceramic particles used in the raw powder determines the degree of progress of erosion as the impact of sandblasting depends on the size of a medium.

Such erosion should be handled in particular when a substrate subjected to ceramic coating is a brittle organic material other than glass or metal. To toughen the surface of a substrate by ceramic coating, just attaching raw powder to the surface is not satisfactory. Measures should be taken to strike the balance between the erosion of a substrate and formation of a tough metal oxide surface by ceramic coating by the AD method.

The powder of the present disclosure was obtained by repeating experiments for achieving this balance, which satisfies the conditions (1) and (2) mentioned above. By satisfying the condition (1) that the powder has peaks of a particle size in a range of from 0.1 to less than 5 μm and a range of from 5 to less than 50 μm in a frequency distribution curve based on the volume-based particle size distribution obtained by a laser diffraction method, a formed surface layer of the powder has a dynamically high strength and the film is efficiently formed by the ceramic coating at the same time unlike a green compact just attached to the surface of a substrate.

To enhance the features of the present disclosure, in the condition (1), the peaks of the particle diameter are more preferably in a range of from 1 to 2 μm and in a range of from 10 to 12 μm. The particle size distribution in the condition (1) can be adjusted by the particle size of ceramic particles at the time of charging. The distribution can be also adjusted by placing ceramic particles in a dry disperser the parameters of which are adjusted.

In the present disclosure, the particle size distribution in the condition (1) is measured under the following conditions.

A laser diffraction particle size distribution measuring device: MT3300EX II, manufactured by MicrotracBEL Corp.
Measurement mode: Dry
Pressurized air used for dispersing a sample during measurement: 0.15 MPa
Temperature and humidity environment during measurement: 23±1 degrees C., 50±3 percent RH

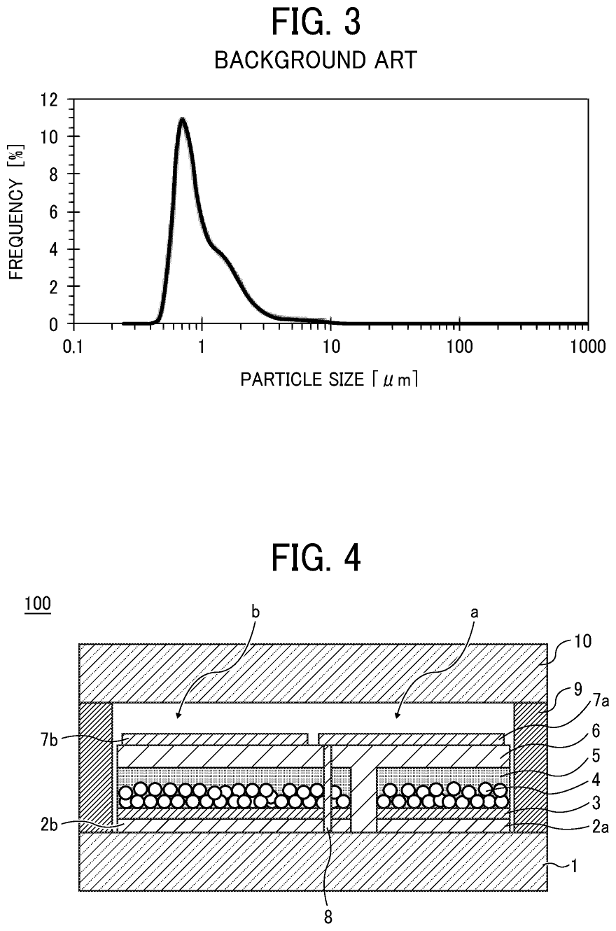

FIG. 2 is a graph illustrating the particle size distribution of the powder obtained in Example 1 described later. In FIG. 2, the peaks referred to in the above condition (1) are present at 1.8 μm and 11.6 μm. “peak” means the highest peak in each particle size range in the condition (1). FIG. 3 is a graph illustrating a particle size distribution by a typical ceramic coating using the same powder as in FIG. 2. This distribution is not satisfactory. There is only one peak under the condition (1).

The toughness of the surface of a metal oxide formed by the AD method depends on the bulk density of raw powder. Inferentially, the particle density of the aerosol sprayed by the AD method acts on the film quality; however, the details are not clear. The bulk density is calculated according to Japanese Industrial Standard JIS R1628 1997 format (Method for Measuring Bulk Density of Fine Ceramic Powder).

Initial bulk density is related to the ease of aerosol formation. The tap density affects the denseness of the film at film-forming. The inventors of the present invention have found that the range optimal for these density variations is present in order to produce a uniform and tough surface of a metal oxide. The powder of the present disclosure was obtained by repeating experiments for identifying this range. A tough and uniform surface of a metal oxide can be obtained more easily by the AD method using powder having the following relationship about the difference between the tap density and the initial bulk density as in the condition (2).

0.88 g/cm³≤(tap density-initial bulk density)≤0.94 g/cm³.

To produce a tougher surface, the initial bulk density in the condition (2) is preferably from 0.9 to 1.0 g/cm³. The difference (tap density-initial bulk density) is more preferably from 0.89 to 0.94 g/cm³.

The bulk density can be readily adjusted by changing the particle size of powder or introducing an appropriate amount of a known additive. The bulk density readily decreases by reducing the average particle diameter of the particle size of a powder. A raw powder having a small average particle diameter is therefore suitable to decrease the bulk density. By dispersing powdered particles placed in a dry disperser with an increased dispersion time or electric power, the average particle diameter of the retrieved powder can be reduced.

Preferred specific examples of the additive include, but are not limited to, fumed silica, fumed alumina, fumed titania.

The metallic oxide contained in the powder of the present disclosure is not particularly limited. Specific examples include, but are not limited to, CoO, NiO, FeO, Bi₂O₃, MoO₂, Cr₂O₃, SrCu₂O₂, CaO-AI₂O₃, Cu₂O, CuAlO, CuAlO₂, and CuGaO₂. Of these, a metal oxide containing either or both of an aluminum and copper element is preferable.

The main component in the powder of the present disclosure is the above-mentioned metal oxide. The powder may optionally contain substances such as additives for improving fluidization and anti-caking properties.

The laminate of the present disclosure includes a layer containing the powder of the present disclosure.

FIG. 4 is a diagram illustrating a view a perovskite solar cell, an example of the laminate of the present disclosure.

As illustrated in FIG. 4, a perovskite solar battery module 100 includes a photoelectric conversion element on a first substrate 1, the photoelectric conversion element including first electrodes 2a and 2b, a dense electron transport layer (dense layer) 3, a porous electron transport layer (porous layer) 4, a perovskite layer 5, a hole transport layer 6, and second electrodes 7a and 7b.

Either of the first electrodes 2a and 2b and either of the second electrodes 7a and 7b have through portions 8 electrically connected to the terminals for extracting electrodes. In the perovskite solar battery module 100, a second substrate 10 is disposed opposite to the first substrate 1 so as to sandwich the photoelectric conversion element, and a sealing member 9 is disposed between the first substrate 1 and the second substrate 10.

In the perovskite solar battery module 100, the first electrodes 2a and the first electrodes 2b are separated from each other by the hole transport layer 6, which is an extended continuous layer. In FIG. 4, a and b represent photoelectric transducers.

One of the electron transport layer, the perovskite layer, and the hole transport layer can be formed using the powder of the present disclosure.

The laminate of the present disclosure may have the layer containing the powder of the present disclosure on a layer containing an organic material. The layer containing the powder of the present disclosure can be provided by a known AD method.

The layer containing an organic material includes a plastic substrate.

The layer containing the powder of the present disclosure has a thickness of, for example, from 0.1 to 100 μm and preferably from 0.3 to 10 μm.

In an embodiment of the present disclosure, the laminate includes a layer containing an organic material, a layer containing a silicone compound adjacent to the layer containing an organic material, and a layer containing the powder of the present disclosure adjacent to the layer containing a silicone compound.

The layer containing a silicone compound is not particularly limited as long as it has a polysiloxane structure, and can be suitably selected to suit to a particular application. The layer containing silicone having a polysiloxane structure prevents peeling-off of the layer containing the powder of the present disclosure.

One way of forming the layer containing a silicone compound is to crosslink an organosilicon compound having either a hydroxyl group or a hydrolyzable group. This layer may optionally contain additives such as a catalyst, a crosslinking agent, an organosilica sol, and a silane coupling agent, and a polymer such as an acrylic polymer.

The method of crosslinking is not particularly limited and can be suitably selected to suit to a particular application. Heat crosslinking is preferable.

Examples of the organosilicon compound having one of a hydroxyl group and a hydrolyzable group include, but are not limited to, a compound having an alkoxysilyl group, a partial hydrolytic condensate of a compound having an alkoxysilyl group, and a mixture thereof.

Examples of the compound having an alkoxysilyl group include tetraalkoxysilanes such as tetraethoxysilane, alkyltrialkoxysilanes such as methyltriethoxysilane, and aryltrialkoxysilanes such as phenyltriethoxysilane.

Compounds in which an epoxy group, a methacryloyl group, or a vinyl group is introduced into these compounds having an alkoxysilyl group can also be used.

One way of producing the partial hydrolytic condensate of the compound having an alkoxysilyl group is to add a predetermined amount of water and an additive such as a catalyst to the compound having an alkoxysilyl group to allow reaction.

Specific examples the raw material of the layer containing the silicone layer include, but are not limited to, GR-COAT (manufactured by Daicel Chemical Industries, Ltd.), Glass Resin (manufactured by Owens-Corning Inc.), Heatless Glass (manufactured by Ohashi Chemical Industries Ltd.), NSC (manufactured by Nippon Seika Chemicals Co., Ltd.), glass stock solutions GO150SX and GO200CL (manufactured by Fine Glass Technology Co., Ltd.), and MKC silicate (manufactured by Mitsubishi Chemical Corp.), silicate/acrylic varnish XP-1030-1 (manufactured by Dainippon Color Materials Co., Ltd.) and NSC-5506 (manufactured by Nippon Fine Chemical Co., Ltd.).

The silicone-containing layer may contain a monoalkoxysilane such as trimethylethoxysilane, trimethylmethoxysilane, tripropylethoxysilane, or trihexylethoxysilane as a constituent component to prevent cracking.

### EXAMPLES

The present disclosure is described in detail below referring to Examples and Comparative Examples, but is not limited thereto. In Examples, part means part by mass unless otherwise specified.

### Example 1

A liquid for coating an intermediate layer was applied to the surface of a substrate with a doctor blade, followed by heat-drying to form an intermediate layer having a thickness of 2 μm on the surface. A powder containing a metal oxide as a raw material was sprayed onto the intermediate layer by aerosol deposition (AD method). A metal oxide-organic hybrid member having an outermost surface layer formed of a metal oxide was thus obtained. The film-forming conditions of each layer and materials for the film-forming are as follows.

### Conditions for Coating Intermediate Layer

The coating material was swept using a doctor blade (YD type, manufactured by Mitutoyo Seiki Co., Ltd.) to form a film.

The gap between the substrate and the doctor blade during sweeping was set to 50 μm.

### Heating and Drying Conditions of Intermediate Layer

Subsequent to drying by heating at 75 degrees C. for 20 minutes, the intermediate layer was dried by heating at 120 degrees C. for 20 minutes.

### Substrate

Polyester films (Lumirror 75T60, manufactured by Toray Industries, Inc.)

### Liquid for Coating Intermediate Layer

The following materials were placed in a vessel, followed by mixing and stirring to obtain a homogeneous liquid mixture. PSZ balls having a diameter of φ of 1 mm were charged so as to occupy 40 percent by volume of the entire vessel, and the liquid mixture was subjected to a ball-mill dispersion treatment at 120 rotation per minute (rpm) for 18 hours.

### Material of Liquid Applied to Intermediate Layer

Silicone oligomer (KR401, manufactured by Shin-Etsu Chemical Co., Ltd.): 333 parts
Silica (AEROSIL NA50A, manufactured by Nippon Aerosil Co., Ltd.): 167 parts
Cyclopentanone (manufactured by Tokyo Chemical Industry Co. Ltd.): 444 parts
Tetrahydrofuran (manufactured by Mitsubishi Chemical Corporation): 1,556 parts

### Condition of Forming Film by AD Method

Moisture content in powder: 0.2 percent or less (value measured by Karl Fischer moisture meter)
Dew-point temperature when powder is charged into vessel:-50 degrees C. or lower
Aerosolized gas species: Dry air
Flow rate of aerosolized gas: 5 L/min (total amount)
Degree of vacuum in the film-forming chamber: 50 Pa
Angle between nozzle and coating sample: 90 degrees
Distance between nozzle and coating sample: 15 mm
Coating Speed: 20 mm/min
Number of applications: 6 times (3 reciprocations)

### Powder Used in AD Method

A mixture obtained by adding an additive to the granular metal oxide 1 so as to be 0.2 percent by mass of the entire powder was used.

### Raw Powder

Metal oxide 1 (copper-aluminum oxide): 99.8 parts·Additive (Reolosil ZD30S, manufactured by Tokuyama): 0.2 parts

Metal Oxide 1 was prepared as follows.

### Manufacturing of Metal Oxide Powder 1

A total of 2 kg of copper oxide (I) (NC-803, manufactured by Nippon Chemical Industrial CO., LTD.) and 1.43 kg of alumina (AA-03, manufactured by Sumitomo Chemical Company) were mixed and heated at 1,100 degrees C. for 40 hours to obtain a copper-aluminum oxide. The oxide obtained was pulverized with a dry disperser (Drystar SDA1, manufactured by Ashizawa Finetech Co., Ltd.). The pulverization conditions were adjusted in such a manner that the particle size distribution in the above mentioned condition (1) of the present disclosure had two peaks of the first peak (0.1 to less than 5 μm) and the second peak (5 to less than 50 μm).

The particle size distribution shown in the condition (1) was measured under the following conditions.

A laser diffraction particle size distribution measuring device: MT3300EX II, manufactured by MicrotracBEL Corp.
Measurement mode: Dry
Pressurized air used for dispersing a sample during measurement: 0.15 MPa
Temperature and humidity environment during measurement: 23±1 degrees C., 50±3 percent RH

The tap density and the initial bulk density in the condition (2) were determined according to JIS R1628 1997 format (Method for Measuring the Bulk Density of Fine Ceramic Powder).

### Example 2

A metal oxide-organic hybrid member was obtained in the same manner as in Example 1 except that the powder subjected to the AD method used in Example 1 was changed to the following.

### Raw Powder

Metal oxide 1 (copper-aluminum oxide): 99.5 parts·Additive (Reolosil ZD30S, manufactured by Tokuyama): 0.5 parts

### Example 3

A metal oxide-organic hybrid member was obtained in the same manner as in Example 1 except that the powder subjected to the AD method used in Example 1 was changed to the following.

### Raw Powder

Metal oxide 1 (copper-aluminum oxide): 99.0 parts
Additive (Reolosil ZD30S, manufactured by Tokuyama): 1.0 part

### Comparative Example 1

A metal oxide-organic hybrid member was obtained in the same manner as in Example 1 except that the powder subjected to the AD method used in Example 1 was changed to the following.

### Raw Powder (Material for Dispersing Element)

Metal oxide 1 (copper-aluminum oxide): 100.0 parts

### Comparative Example 2

A metal oxide-organic hybrid member was obtained in the same manner as in Example 1 except that the powder subjected to the AD method used in Example 1 was changed to the following.

### Raw Powder

Metal oxide 1 (copper-aluminum oxide): 98.0 parts
Additive (Reolosil ZD30S, manufactured by Tokuyama): 2.0 parts

The metal oxide-organic hybrid members of Examples 1 to 3 and Comparative Examples 1 and 2 described above were subjected to a scratch test. After the scratch test, the scratch site was observed with a confocal microscope to evaluate the depth of the groove scratched in the test.

The depth of the groove depends on the set load of the stylus in the scratch test. The coefficient α obtained from the following approximate straight line of the change rate of the groove depth against load was determined as the evaluation index.

Groove depth=α×(load)+intercept (Equation 1)

### Scratch Test

Tester: Ultra-thin film scratch tester CSR-2000 (manufactured by RHESCA Co., LTD.)
Scratch speed: 10 μm/s
Spring constant: 100 g/mm
Stylus diameter: 5 μmR
Excitation level: 100 μm
Excitation frequency: 45 Hz
Set load: 5, 7, 9, 11, 13, 15 (mN)

### Observation of Groove Depth

Tester: Confocal microscope OPTELICS H-1200 (manufactured by Lasertec Corporation)
Lens Magnification: 50×
Light source: white

The evaluation results are shown in the following Tables. Table 1 shows the particle size distribution under the condition (1) of the present disclosure. Table 2 shows the bulk density under the condition (2) of the present disclosure. Table 3 shows the results of the scratch test of the laminates.

TABLE 1

| | Peak (μm) | |
|---|---|---|
| Example 1 | 1.8 | 11.6 |
| Example 2 | 1.8 | 10.1 |
| Example 3 | 1.8 | 11.0 |
| Comparative | 1.8 | 12.0 |
| Example 1 | | |
| Comparative | 1.8 | 11.0 |
| Example 2 | | |

TABLE 2

| | | | Tap density-initial |
|---|---|---|---|
| | Initial bulk density | Tap density | bulk density |
| | (g/cm³) | (g/cm³) | (g/cm³) |
| Example 1 | 1.00 | 1.88 | 0.88 |
| Example 2 | 0.99 | 1.88 | 0.89 |
| Example 3 | 0.94 | 1.88 | 0.94 |
| Comparative | 1.02 | 1.88 | 0.86 |
| Example 1 | | | |
| Comparative | 0.92 | 1.88 | 0.96 |
| Example 2 | | | |

TABLE 3

| | α |
|---|---|
| | (μm/mN) |
| Example 1 | 0.043 |
| Example 2 | 0.030 |
| Example 3 | 0.035 |
| Comparative | 0.055 |
| Example 1 | |
| Comparative | 0.060 |
| Example 2 | |

The metal oxide-organic hybrid members of Examples 1, 2 and 3 are tougher than the members of Comparative Examples 1 and 2.

As seen in the results of the scratch tests of these members, the metal oxide organic hybrid member of Example 2 was the toughest. As seen in the results of Examples and Comparative Examples, the difference between the tap bulk density and the initial bulk density determines the toughness of the metal oxide surface of the member obtained as a final product. This difference being from 0.88 to 0.94 g/cm³ in the present disclosure plays a role of determining the level of the toughness of a member.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

This patent application is based on and claims priority to Japanese Patent Application No. 2021-150973 filed on Sep. 16, 2021 in the Japan Patent Office, the entire disclosure of which is hereby incorporated by reference herein.

### REFERENCE SIGNS LIST

1 First substrate
2, 2a, and 2b First electrode
3 Dense electron transport layer (dense layer)
4 Porous electron transport layer (porous layer)
5 Perovskite layer
6 Hole transport layer
7, 7a, and 7b Second electrode
8. Through portion
9. Sealing member
10 Second substrate
100 Photoelectric transduction module
a, b Photoelectric transducer
11 Ceramic particle
12 Crack
13 Active new surface

1. A powder, comprising:
a metal oxide, wherein the powder satisfies the following conditions (1) and (2):
(1) the powder has peaks of a particle size in a range of from 0.1 to less than 5 μm and in a range of from 5 to less than 50 μm in a frequency distribution curve based on a volume-based particle size distribution obtained by a laser diffraction method; and
(2) a difference between a tap density and an initial bulk density satisfies the following relationship:
0.88 g/cm³≤(tap density−initial bulk density)≤0.94 g/cm³.

2. The powder according to claim 1, wherein the peaks are in a range of from 1 to less than 2 μm and in a range of from 10 to 12 μm.

3. The powder according to claim 1, wherein the initial bulk density is in a range of from 0.9 to 1.0 g/cm³.

4. The powder according to claim 1, wherein the metal oxide comprises at least one selected from the group consisting of an aluminum element and a copper element.

5. A laminate, comprising:
a layer containing the powder of claim 1.

6. The laminate according to claim 5,
further comprising a layer containing an organic material,
wherein the layer containing the powder is disposed on the layer containing the organic material.

7. The laminate according to claim 6,
further comprising a layer containing a silicone compound,
wherein the layer containing the silicone compound is disposed adjacent to both of the layer containing the organic material and the layer containing the powder.

8. A method of manufacturing a laminate, the method comprising:
manufacturing a layer containing the powder of claim 1 by an aerosol deposition method; and
laminating the layer containing the powder on a layer containing an organic material.
